(19) United States
(12) Patent Application Publication
(10) Pub. No.: US 2011/0094783 A1
(43) Pub. Date: Apr. 28, 2011

(54) PRINTED CIRCUIT BOARD

(75) Inventors: HUA-LI ZHOU, Shenzhen City (CN); CHIA-NAN PAI, Tu-Cheng (TW); SHOU-KUO HSU, Tu-Cheng (TW)

(73) Assignees: HONG FU JIN PRECISION INDUSTRY (ShenZhen) CO., LTD., Shenzhen City (TW); HON HAI PRECISION INDUSTRY CO., LTD., Tu-Cheng (TW)

(21) Appl. No.: 12/647,396

(22) Filed: Dec. 25, 2009

(30) Foreign Application Priority Data
Oct. 28, 2009 (CN) 200910308911.X

(51) Int. Cl. H05K 1/16

(52) U.S. Cl. 174/260

(57) ABSTRACT

A printed circuit board (PCB) includes a signal plane and a reference plane. The signal plane includes a pad, a passive element mounted on the pad, and a signal transmission line electrically connected to the passive element via the pad. The reference plane provides a return path for a signal transmitted through the passive element and the transmission line. A void is defined in the reference plane corresponding to the passive element, to increase a length of the return path.

### CROSS-REFERENCE TO RELATED APPLICATION

Relevant subject matter is disclosed in a co-pending U.S. patent application (Attorney Docket No. US28434) filed on the same date and having a title of “PRINTED CIRCUIT BOARD”, which is assigned to the same assignee as this patent application.

### BACKGROUND

1. Technical Field

The present disclosure relates to printed circuit boards (PCBs) and, particularly, to a PCB which can improve signal integrity passing through the PCB.

2. Description of Related Art

In a PCB design process, high-speed serial signal lines are usually electrically connected to passive elements, such as resistors or capacitors, via pads mounted on the PCB.

Referring to FIG. 1, an ordinary PCB 10 includes a signal plane and a reference plane 12 which is an integrated plane without any gap arranged under the signal plane for providing a return path of signals. A passive element, such as a resistor R, and a signal transmission line 14 are arranged on the signal plane, and the resistor R is electrically connected to the signal transmission line 14 via a pad 18. A signal transmitted through the resistor R and the signal transmission line 14 will be returned in the reference plane 12 and under the signal transmission line 14 (see a return path 16). Because a width of the pad 18 is greater than a width of the signal transmission line 14, characteristic impedance changes sharply from the transmission line 14 to the pad 18, which may influence signal integrity.

FIG. 2 shows a graph of the characteristic impedance from the transmission line 14 to the pad 18 when the resistor R is a 0402 size specification, and Wpad=20 mils, Spad=54 mils, Wtrace=5 mils. FIG. 3 shows a graph of the characteristic impedance from the transmission line 14 to the pad 18 when the resistor R is a 0603 size specification, and Wpad=30 mils, Spad=88 mils, Wtrace=5 mils. FIG. 4 shows a graph of the characteristic impedance from the transmission line 14 to the pad 18 when the resistor R is a 0805 size specification, and Wpad=50 mils, Spad=130 mils, Wtrace=5 mils. Wherein Wpad is a width of the pad 18, Spad is a length of the pad 18, Wtrace is a width of the signal transmission line 14. Obviously, the signal integrity of the PCB 10 is poor.

### BRIEF DESCRIPTION OF THE DRAWINGS

FIG. 1 is a schematic view of a related-art printed circuit board (PCB), including a resistor, a signal transmission line arranged on a signal plane, the resistor electrically connected to the signal transmission line via a pad.

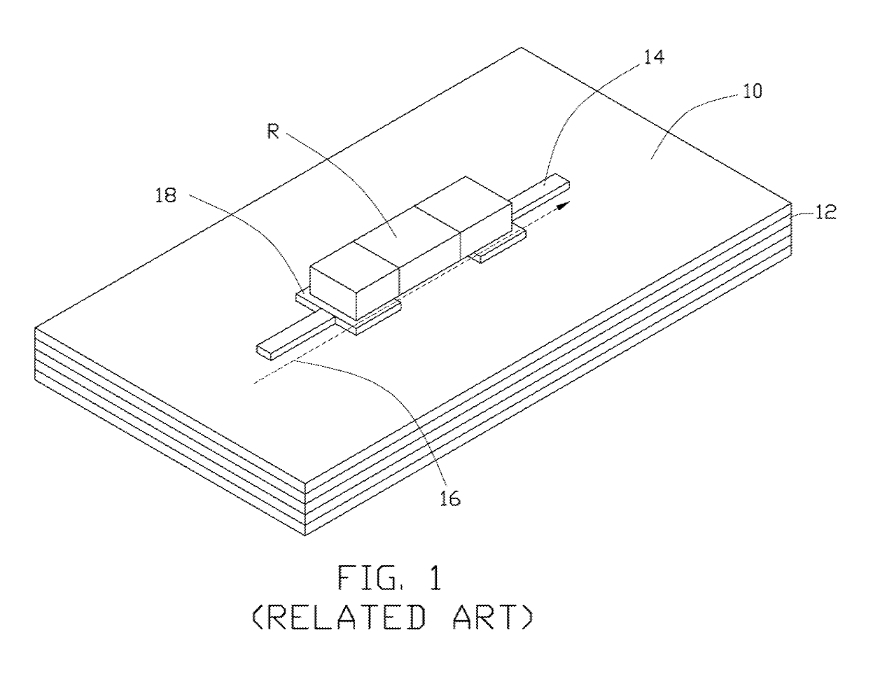

FIG. 2 is a graph of the characteristic impedance from the transmission line to the pad of the related-art PCB of FIG. 1, in response to the resistor being 0402 size.

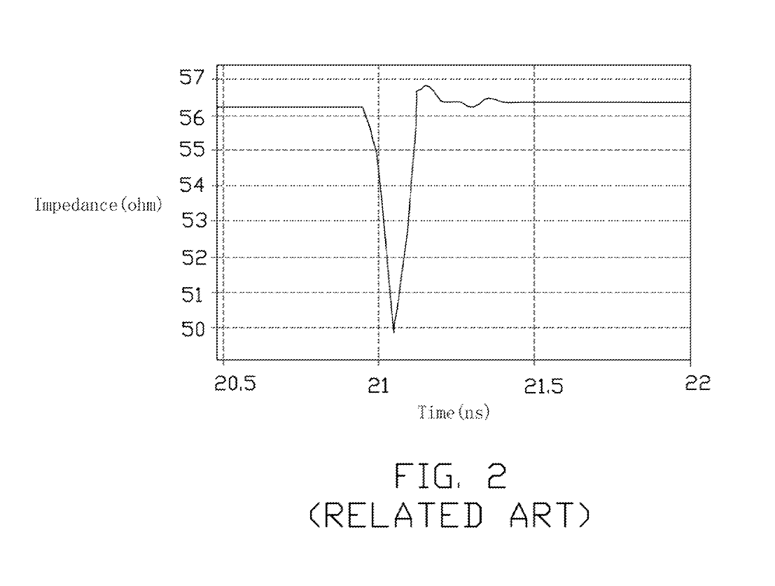

FIG. 3 is a graph of the characteristic impedance from the transmission line to the pad of the related-art PCB of FIG. 1, in response to the resistor being 0603 size.

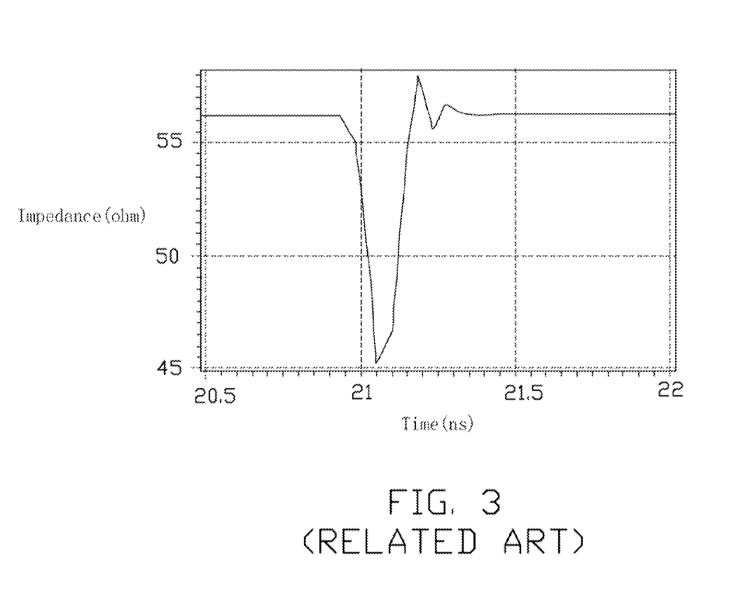

FIG. 4 is a graph of the characteristic impedance from the transmission line to the pad of the related-art PCB of FIG. 1, in response to the resistor being 0805 size.

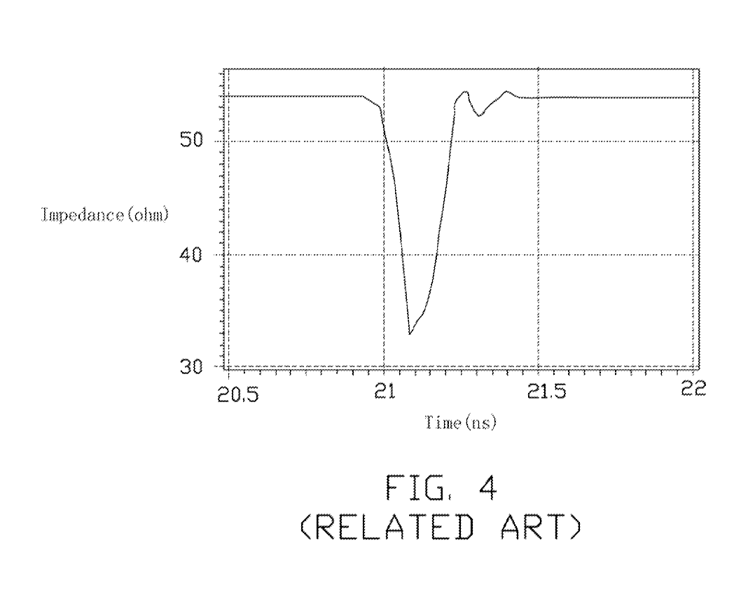

FIG. 5 is a schematic view of an exemplary embodiment of a PCB, including a reference plane, a passive element, and a signal transmission line arranged on a signal plane, the passive element electrically connected to the signal transmission line via a pad.

FIG. 6 is a schematic view of the reference plane of the PCB of FIG. 5.

FIG. 7 is a cross-sectional view of the PCB of FIG. 5, taken along line VII-VII.

FIG. 8 is a graph of the characteristic impedance from the transmission line to the pad of the PCB of FIG. 5, in response to the passive element being 0402 size.

FIG. 9 is a graph of the characteristic impedance from the transmission line to the pad of the PCB of FIG. 5, in response to the passive element being 0603 size.

FIG. 10 is a graph of the characteristic impedance from the transmission line to the pad of the PCB of FIG. 5, in response to the passive element being 0805 size.

### DETAILED DESCRIPTION

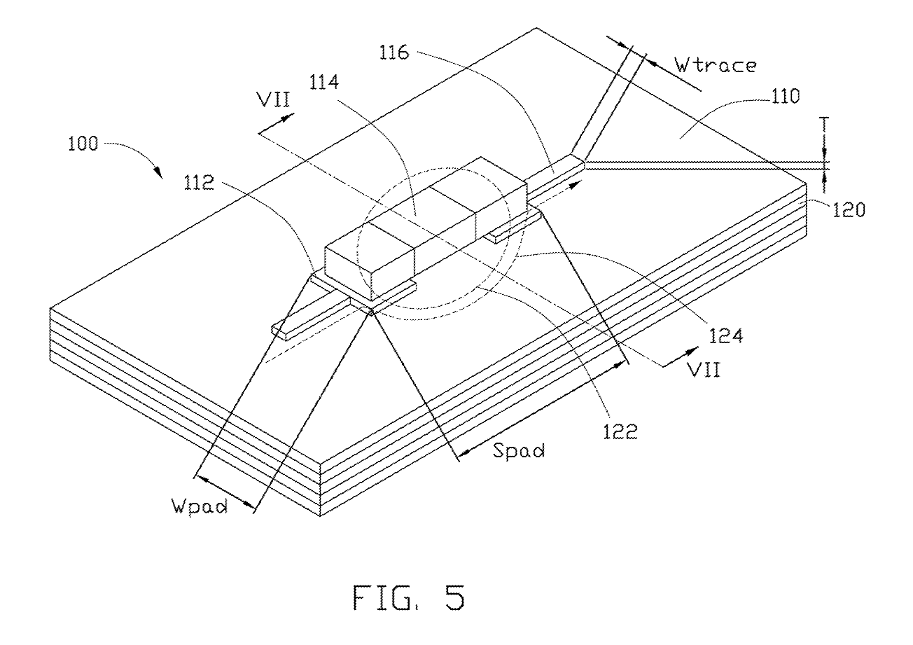

Referring to FIG. 5, an exemplary embodiment of a printed circuit board (PCB) 100 includes a signal plane 110 and a reference plane 120. It may be understood that the PCB 100 also includes other planes, such as a power plane. These other planes fall within well-known technologies, and are therefore not described here.

The signal plane 110 includes a pad 112 for mounting a passive element 114, such as a resistor or a capacitor. A signal transmission line 116 is mounted on the signal plane 110 and electrically connected to the passive element 114 via the pad 112. The reference plane 120 is used to provide a return path of signals, such as high-speed serial signals, transmitted through the signal transmission line 116 and the passive element 114.

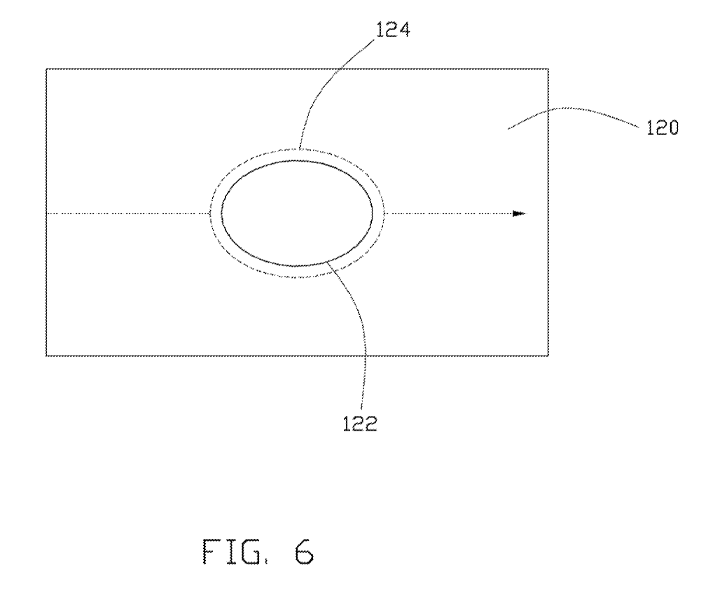

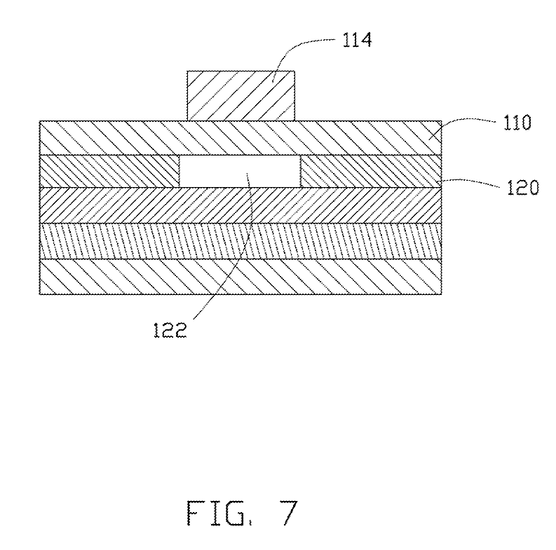

Referring to FIGS. 6 and 7, the reference plane 120 defines an elliptic-shaped void 122 corresponding to the passive element 114. In other embodiments, the shape of the void 122 can be rectangle, round, and so on. Because a portion under the passive element 114 of the reference plane 120 is a void, a signal transmitted through the passive element 114 and the signal transmission line 116 will be returned in the reference plane 120 and rounds the void 122 (see a return path 124), therefore the return path 124 is greater, a characteristic impedance from the signal transmission line 116 to the pad 112 does not undergo mutation, which can improve signal integrity.

When the passive element 114 is a surface mounted component and the size specification of the passive element 114 is 0402, an area S0402 of the void 122 satisfies the following formula:

$$S 0402 \approx 1.7 * {( \frac{4 Wpad + 5 T}{0.8 Wtrace + T} )}^{2} π ,$$

### and Wpad≦W1≦2Wpad, 0.8W1≦W2≦3.5W1.

Wherein, Wpad is a width of the pad 112, Spad is a length of the pad 112, Wtrace is a width of the signal transmission line 116, T is a height of the signal transmission line 116, W1 is a length of a minor axis of the void 122, and W2 is a length of a major axis of the void 122.

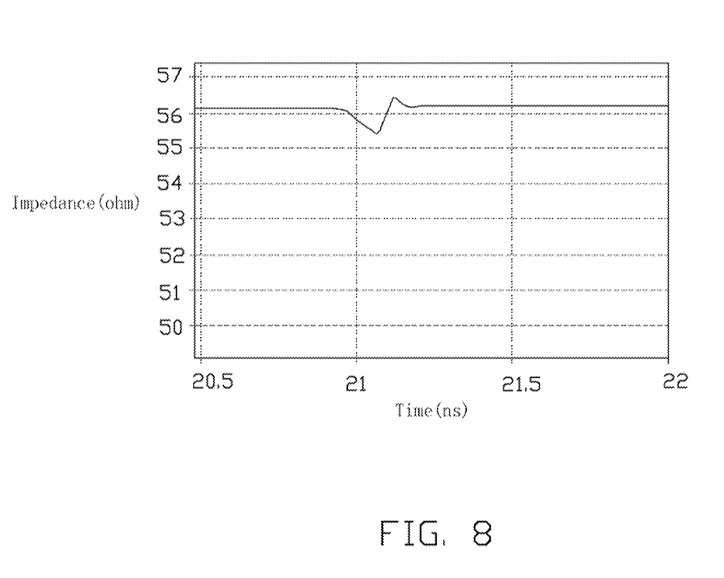

Referring to FIG. 8, the passive element 114 is a 0402 size specification, and Wpad=20 mils, Spad=54 mils, Wtrace=5 mils, S0402=1258 mils². Obviously, the signal integrity of the PCB 100 is better than the signal integrity of the PCB 10.

When the passive element 114 is a surface mounted component and the size specification is 0603, an area S0603 of the void 122 satisfies the following formula:

$$S 0603 \approx 2.0 * {( \frac{4 Wpad + 5 T}{0.8 Wtrace + T} )}^{2} π ,$$

### and Wpad≦W1≦2Wpad, 1.5W1≦W2≦3.5W1.

When the passive element 114 is a surface mounted component and the size specification is 0805, an area S0805 of the void 122 satisfies the following formula:

$$S 0805 \approx 2.1 * {( \frac{4 Wpad + 5 T}{0.8 Wtrace + T} )}^{2} π ,$$

### and Wpad≦W1≦2Wpad, 1.5W1≦W2≦2.5W1.

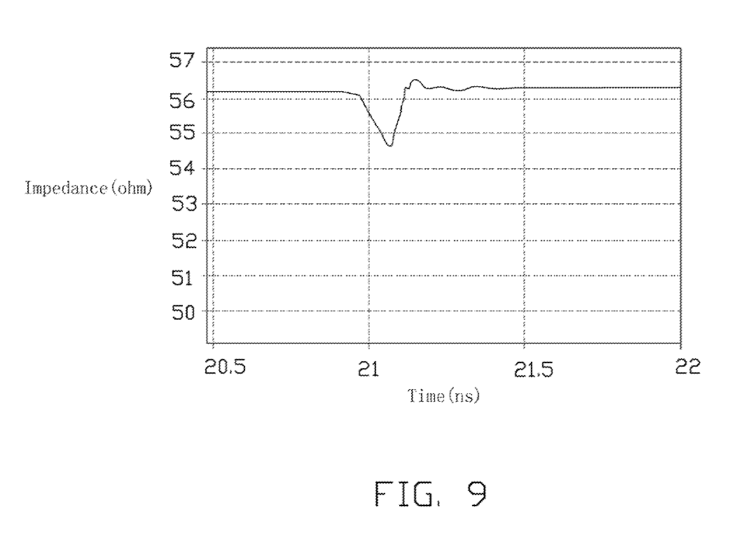

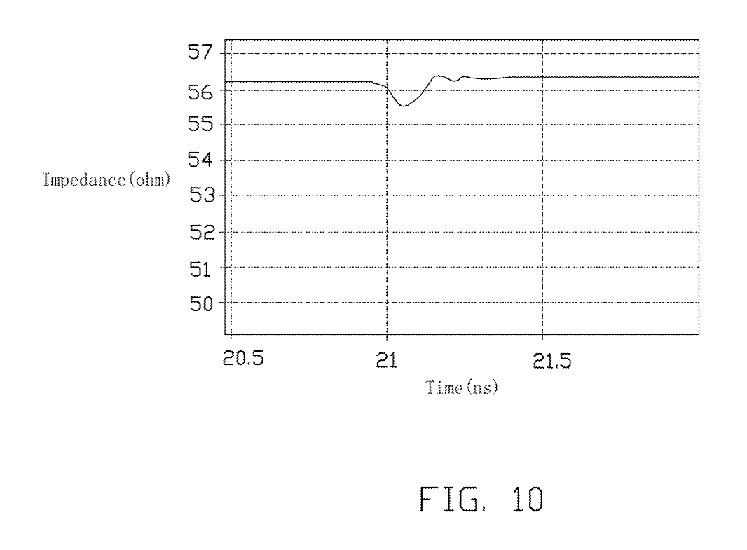

Referring to FIG. 9, the passive element 114 is a 0603 size specification, and Wpad=30 mils, Spad=88 mils, Wtrace=5 mils, S0603=3103 mils². Referring to FIG. 10, the passive element 114 is a 0805 size specification, and Wpad=50 mils, Spad=130 mils, Wtrace=5 mils, S0805=8550 mils². Obviously, the signal integrity of the PCB 100 is better than the signal integrity of the PCB 10.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board (PCB) comprising:
a signal plane comprising a pad, a passive element mounted on the pad, and a signal transmission line electrically connected to the passive element via the pad; and
a reference plane to provide a return path for a signal transmitted through the passive element and the transmission line, wherein a void is defined in the reference plane corresponding to the passive element, to increase a length of the return path.

2. The PCB of claim 1, wherein the void is elliptic-shaped.

3. The PCB of claim 2, wherein the passive element is a surface mounted component and the size specification of the surface mounted component is 0402, an area S0402 of the void satisfies the following formula:
$$S 0402 \approx 1.7 * {( \frac{4 Wpad + 5 T}{0.8 Wtrace + T} )}^{2} π ,$$
and Wpad≦W1≦2Wpad, 0.8W1≦W2≦3W1, wherein Wpad is a width of the pad, Spad is a length of the pad, Wtrace is a width of the signal transmission line, T is a height of the signal transmission line, W1 is a length of a minor axis of the void, and W2 is a length of a major axis of the void.

4. The PCB of claim 3, wherein Wpad=20 mils, Spad=54 mils, Wtrace=5 mils, S0402=1258 mils².

5. The PCB of claim 2, wherein the passive element is a surface mounted component and the size specification of the surface mounted component is 0603, an area S0603 of the void satisfies the following formula:
$$S 0603 \approx 2.0 * {( \frac{4 Wpad + 5 T}{0.8 Wtrace + T} )}^{2} π ,$$
and Wpad≦W1≦2Wpad, 1.5W1≦W2≦3.5W1, wherein Wpad is a width of the pad, Spad is a length of the pad, Wtrace is a width of the signal transmission line, T is a height of the signal transmission line, W1 is a length of a minor axis of the void, and W2 is a length of a major axis of the void.

6. The PCB of claim 5, wherein Wpad=30 mils, Spad=88 mils, Wtrace=5 mils, S0603=3103 mils².

7. The PCB of claim 2, wherein the passive element is a surface mounted component and the size specification of the surface mounted component is 0805, an area S0805 of the void satisfies the following formula:
$$S 0805 \approx 2.1 * {( \frac{4 Wpad + 5 T}{0.8 Wtrace + T} )}^{2} π ,$$
and Wpad≦W1≦2Wpad, 1.5W1≦W2≦2.5W1, wherein Wpad is a width of the pad, Spad is a length of the pad, Wtrace is a width of the signal transmission line, T is a height of the signal transmission line, W1 is a length of a minor axis of the void, and W2 is a length of a major axis of the void.

8. The PCB of claim 7, wherein Wpad=50 mils, Spad=130 mils, Wtrace=5 mils, S0805=8550 mils².

9. The PCB of claim 1, wherein the passive element is a resistor or a capacitor.

10. The PCB of claim 1, wherein the signal transmission line is a high-speed serial signal trace, to transmit high-speed serial signals.
